(19) United States
(12) Patent Application Publication
(10) Pub. No.: US 2023/0187237 A1
(43) Pub. Date: Jun. 15, 2023

(54) OPTICAL HEATING METHOD AND OPTICAL HEATING APPARATUS FOR HEATING WIDE BAND GAP SEMICONDUCTOR

(71) Applicant: Ushio Denki Kabushiki Kaisha, Tokyo (JP)

(72) Inventor: Takahiro Inoue, Tokyo (JP)

(73) Assignee: Ushio Denki Kabushiki Kaisha, Tokyo (JP)

(21) Appl. No.: 17/856,126

(22) Filed: Jul. 1, 2022

(30) Foreign Application Priority Data
Dec. 9, 2021 (JP) 2021-200026

(51) Int. Cl. H01L 21/67

(52) U.S. Cl. CPC H01L 21/67115; H01L 25/0753

(57) ABSTRACT

An optical heating method includes a process (a) in which an object to be treated containing a wide band gap semiconductor is irradiated with ultraviolet light having a peak wavelength in a range of 175 nm to 370 nm emitted from a UV-LED light source through a window member to heat the object to be treated.

### CROSS-REFERENCE TO RELATED APPLICATION(S)

This application claims priority from Japanese Patent Application No. 2021-200026. The entire teachings of the above application are incorporated herein by reference.

### TECHNICAL FIELD

The present invention relates to optical heating methods, and in particular to an optical heating method for an object to be treated that contains a type of semiconductor referred to as a “wide band gap semiconductor”. The present invention also relates to an optical heating apparatus for heating the wide band gap semiconductor.

### BACKGROUND ART

Semiconductor manufacturing processes involve various types of heat treatments including a deposition treatment, an oxidation diffusion treatment, a modification treatment, and an annealing treatment on objects to be treated, such as semiconductor wafers. These heat treatments often use optical irradiation. The process of using light to heat objects to be treated is referred to as “optical heating”.

The patent document 1 below, for example, discloses a heating apparatus that uses optical heating for manufacturing semiconductors. The apparatus in Patent Document 1 uses LED (light-emitting diode) lamps as its light source, emitting light with a wavelength of 810 nm to 980 nm.

Patent Document 1: JP-A-2020-009927

Non Patent Document 1: Brinkmann, R. T., et. al., “Atomic and Molecular Species”, The Middle Ultraviolet: Its Science and Technology. Part of the Wiley Series in Pure and Applied Optics. Edited by A. E. S. Green. Published by John Wiley & Sons, Inc., New York, 1966, p. 40

### SUMMARY OF THE INVENTION

In recent years, the development of power semiconductor devices that can be operated at higher voltages and higher currents than conventional devices has been proceeding. Conventional devices typically use Si, however, semiconductor devices using materials with a higher Baliga Figure of Merit than Si are expected to be developed in order to achieve devices that are compact and exhibit high breakdown voltage characteristics. The materials for such semiconductor devices include GaN, Ga₂O₃, and SiC. All of these materials have a wide band gap, exhibiting high breakdown field strength with a thin depletion layer, thus achieving compact and high-voltage devices.

Wide band gap semiconductors refer to semiconductors having a larger band gap than Si, and more specifically, semiconductors having a forbidden bandwidth of 2 eV or greater. These types of semiconductors typically include GaN, Ga₂O₃, and SiC; however they also include ZnO, ZnSe, and diamond.

Because GaN, Ga₂O₃, and SiC, which have a higher Baliga Figure of Merit than Si, are classified as wide band gap semiconductors, light having a wavelength range of 810 nm to 980 nm, which is used by the apparatus in the patent document 1, is transmitted through them. In other words, the light having this wavelength range fails to be used to heat wide band gap semiconductors.

In view of the above-mentioned problems, it is an object of the present invention to provide an optical heating method capable of efficiently heating an object to be treated that contains a wide band gap semiconductor. It is also an object of the present invention to provide an optical heating apparatus suitable for heating an object to be treated that contains a wide band gap semiconductor.

The optical heating method according to the present invention includes a process (a) in which an object to be treated containing a wide band gap semiconductor is irradiated with ultraviolet light having a peak wavelength in a range of 175 nm to 370 nm emitted from a UV-LED light source through a window member to heat the object to be treated.

The optical heating method according to the present invention uses ultraviolet light having a peak wavelength in a range of 175 nm to 370 nm, which is a much shorter wavelength range than that of conventional ultraviolet. The ultraviolet light having this wavelength range is absorbed by the object to be treated to an extent to enable a heating effect, even when the object to be treated contains a wide band gap semiconductor. Thereby this method enables a non-contact heating of the object to be treated.

The window member is made of a material with high transmittance to the ultraviolet light. The transmittance is preferably 50% or higher, more preferably 70% or higher, and especially preferably 80% or higher. When the ultraviolet light has a peak wavelength in a range of 175 nm to 200 nm, the window member is suitably made of synthetic quartz, magnesium fluoride (MgF₂), calcium fluoride (CaF₂) or barium fluoride (BaF₂). In contrast, when the ultraviolet light has a peak wavelength in a range of 200 nm to 370 nm, the window member is suitably made of fused quartz or sapphire in addition to synthetic quartz. The window member made of the above-mentioned materials prevents the window member from absorbing the ultraviolet light to a large extent, enabling the ultraviolet light emitted from a UV-LED light source to be used efficiently for heating the object to be treated.

The optical heating method may include a process (b) in which a radiation thermometer having a sensitivity wavelength range in a predetermined wavelength range of 0.5 μm to 5 μm measures a temperature of the object to be treated by receiving light emitted from the object to be treated during execution of the process (a).

Semiconductor light-emitting elements, which are exemplified by LED devices, are known to emit light having a wavelength range including the peak wavelength with relatively high emission intensity (main emission wavelength range) as well as light having a side of a longer wavelength than the main emission wavelength range with relatively low emission intensity. The light in the side of a long wavelength exhibits a slightly higher emission intensity than the intensity at a tail of the intensity distribution approximated with Gaussian distribution, although the emission intensity itself is very low compared to the intensity in the main emission wavelength range. The light in the side of a long wavelength originates from defects or impurity levels in the active layer, which are unavoidably produced during the manufacturing of semiconductor light-emitting elements, and is referred to as “deep-level emission”.

For example, when a light source having a peak wavelength in a range of 400 nm to 1000 nm is used as a heating light source, the wavelength range of the deep-level emission emitted from this light source with relatively high intensity overlaps with a sensitivity wavelength range of a radiation thermometer. In this case, a part of the light emitted from the heating light source is received by the radiation thermometer, posing a concern of falsely measuring the temperature of the object to be treated.

A radiation thermometer having a sensitivity wavelength range of 0.5 μm to 5 μm can be used to measure a temperature of the object to be treated from a relatively low temperature range such as 200° C. to 500° C., enabling more precise temperature control. The radiation thermometer preferably has a sensitivity wavelength range of 0.7 μm to 4 μm, and more preferably 1 μm to 3 μm from a viewpoint of accurately detecting the temperature of the object to be treated from the initial stage after starting the heating thereof.

The upper limit of the sensitivity wavelength range of the radiation thermometer may be set appropriately in accordance with a melting point of the wide band gap semiconductor materials contained in the object to be treated. However, this configuration does not exclude a radiation thermometer capable of measuring a temperature range higher than the melting point from being used to measure the temperature of the object to be treated.

The ultraviolet light may have a peak wavelength in a range of 190 nm to 370 nm.

Ultraviolet light having a wavelength of less than 190 nm is known to exhibit its increasing absorptance on oxygen (O₂), as described in the above-mentioned Non-Patent Document 1. FIG. 1, which is disclosed in Non Patent Document 1, is a graph illustrating a relationship between a wavelength and absorption coefficients on several substances including O₂.

FIG. 1 shows that the absorption coefficient of ultraviolet light on oxygen (O₂) significantly exhibits an increasing tendency in a wavelength range below 190 nm. For example, the wavelength component near 185 nm in the ultraviolet light emitted from a low-pressure mercury vapor lamp is absorbed by oxygen, then generating atomic oxygen O(³P) with a ground state in accordance with Formula (1).

O₂+hν(185 nm)→O(³P)+O(³P) (1)

This atomic oxygen 0(3P) reacts with oxygen (02) to generate ozone (03) in accordance with Formula (2) below.

O(³P)+O₂→O₃ (2)

In optical heating treatment, a light source is typically installed in the atmosphere. With this view, when a UV-LED light source is installed in the atmosphere according to the method of the present invention, an object to be treated, which is placed in a vacuum environment, is typically irradiated with the ultraviolet light emitted from the UV-LED light source and through a window for light transmission. Hence, when the ultraviolet light contains a wavelength component of less than 190 nm, the ultraviolet light of this wavelength component is absorbed by oxygen in the atmosphere, which may cause ozone to generate in accordance with the above-mentioned Formula (1)-(2).

As described above, the ultraviolet light, which is emitted from the UV-LED light source, having a peak wavelength in a range of 190 nm to 370 nm is effective in suppressing the amount of ozone generation even when the UV-LED light source is installed in the atmosphere. The ultraviolet light emitted from the UV-LED light source is more suitable to have a peak wavelength in a range of 200 nm or longer from the viewpoint of further reducing the amount of ozone generation.

The wide band gap semiconductor may be made of Ga₂O₃ and the ultraviolet light may have a peak wavelength of 300 nm or less.

FIG. 2A is a graph illustrating a relationship between a wavelength and absorptance in Ga₂O₃. FIG. 2A indicates that Ga₂O₃ has an absorptance exhibiting an increasing tendency in a wavelength range of 300 nm and below. In other words, when the object to be treated contains Ga₂O₃, high heating efficiency is achieved by irradiating the object to be treated with ultraviolet light, which is emitted from the UV-LED light source, having a peak wavelength of 300 nm or less. The peak wavelength is preferably 280 nm or less, and is more preferably 260 nm or less.

In particular, FIG. 2A indicates that Ga₂O₃ exhibits an absorptance of 50% or more in a wavelength range of 260 nm or less. Therefore, when the object to be treated contains Ga₂O₃, high heating efficiency is achieved by irradiating the object to be treated with ultraviolet light, which is emitted from the UV-LED light source, having a peak wavelength of 260 nm or less.

FIG. 2B is a graph illustrating a relationship between a wavelength and a penetration depth when Ga₂O₃ is irradiated with light. The vertical axis is expressed in logarithmic scale. FIG. 2B indicates that ultraviolet light having a wavelength of 280 nm has a penetration depth of about 290 nm when Ga₂O₃ is irradiated with light. Further, it is understood the penetration depth becomes shallower as the ultraviolet light wavelength is shorter. FIG. 2B discloses no data of the penetration depth when irradiated with the ultraviolet light in the wavelength range exceeding 280 nm. However, it is apparent from the tendency of the graph that the penetration depth becomes deeper as the wavelength is longer.

In other words, the ultraviolet light having a shorter wavelength, which is to be irradiated, is capable of selectively treating a more vicinity of the surface of the object to be treated containing Ga₂O₃ (e.g., within a range of a depth of 100 nm or less). This ultraviolet light irradiation enables heat treatment on the surface of the object to be treated while suppressing the impact of thermal history or thermal damage to devices that are located in a layer below the surface of the object to be treated.

The wide band gap semiconductor may be made of GaN or SiC and the ultraviolet light may have a peak wavelength of 360 nm or less.

FIG. 3A is a graph illustrating a relationship between a wavelength and absorptance in GaN. FIG. 3A indicates that GaN has an absorptance of approximately 80% when irradiated with ultraviolet light having a wavelength of 360 nm. It is understood that GaN exhibits a sharp declining tendency of the absorptance in a wavelength range beyond 360 nm, or more precisely, in a wavelength range beyond 369 nm, and a relatively high absorptance in a wavelengths range of 360 nm or less. Therefore, when the object to be treated contains GaN, high heating efficiency is achieved by irradiating the object to be treated with the ultraviolet light, which is emitted from the UV-LED light source, having a peak wavelength of 360 nm or less.

FIG. 3B is a graph illustrating a relationship between a wavelength and a penetration depth when GaN is irradiated with light, which is similar to FIG. 2B. FIG. 3B indicates that ultraviolet light having a wavelength of 360 nm has a penetration depth of about 100 nm when GaN is irradiated with light. It is understood that the penetration depth becomes shallower as the wavelength of the ultraviolet light is longer.

Hence, the ultraviolet light having a shorter wavelength, which is to be irradiated, is capable of selectively treating a more vicinity of the surface (e.g., in a range of a depth of 100 nm or less) of the object to be treated containing GaN. This ultraviolet light irradiation enables heat treatment on the surface of the object to be treated while suppressing the impact of thermal history or thermal damage to devices that are located in a layer below the surface of the object to be treated. In the case of attempting to selectively treat a more vicinity of the surface of the object to be treated, the ultraviolet light preferably has a peak wavelength of 360 nm or less, and more preferably 300 nm or less.

FIG. 4A is a graph illustrating a relationship between a wavelength and absorptance in SiC. FIG. 4A indicates that SiC has an absorptance of approximately 50% at ultraviolet light having a wavelength of 360 nm. FIG. 4A indicates that SiC exhibits an absorptance of 40% or more in a wavelength range of 360 nm or less and an absorptance of 50% or more in a wavelength range of 300 nm or less. Therefore, even when the object to be treated contains SiC, high heating efficiency is achieved by irradiating the object to be treated with ultraviolet light, which is emitted from the UV-LED light source, having a peak wavelength of 360 nm or less.

FIG. 4B is a graph illustrating a relationship between a wavelength and a penetration depth when SiC is irradiated with light, which is similar to FIG. 2B. FIG. 4B indicates that when SiC is irradiated with ultraviolet light having a wavelength of 360 nm, SiC has a penetration depth below 100 nm, more specifically approximately 30 nm. It is understood that the penetration depth becomes shallower as the wavelength of the ultraviolet light is longer.

Hence, ultraviolet light having a shorter wavelength, which is to be irradiated, is capable of selectively treating a more vicinity of the surface (e.g., within a range to a depth of 100 nm or less) of the object to be treated containing SiC. This ultraviolet light irradiation enables heat treatment on the surface of the object to be treated while suppressing the impact of thermal history or thermal damage to devices that are located in a layer below the surface of the object to be treated. In the case of attempting to selectively treat a more vicinity of the surface of the object to be treated, the ultraviolet light preferably has a peak wavelength of 360 nm or less and more preferably 300 nm or less.

An optical heating apparatus according to the present invention is an optical heating apparatus for a wide band gap semiconductor, the optical heating apparatus includes:

a chamber that accommodates an object to be treated containing a wide band gap semiconductor;

a supporter that supports the object to be treated in the chamber;

a UV-LED light source that emits ultraviolet light having a peak wavelength in a range of 175 nm to 370 nm; and

a window member that allows the ultraviolet light emitted from the UV-LED light source to pass through and guide the ultraviolet light onto the object to be treated.

The optical heating apparatus described above enables a non-contact yet efficient heating in the treatment of the wide band gap semiconductor used in power semiconductor devices.

In the above configuration, the UV-LED light source may include a plurality of LED substrates on which a plurality of LED elements is mounted, and the plurality of LED substrates may be arranged in a line symmetry, a point symmetry, or a rotational symmetry when viewed in a normal direction of a face of the LED substrates.

The above configuration enables nearly uniform heating of the object to be treated because the light intensity distribution to the object to be treated becomes nearly uniform.

The present invention enables efficient heating of the object to be treated that contains the wide band gap semiconductors.

### BRIEF DESCRIPTION OF DRAWINGS

FIG. 1 is a graph illustrating a relationship between a wavelength and absorption coefficients on several substances including oxygen (O₂).

FIG. 2A is a graph illustrating a relationship between a wavelength and absorptance in Ga₂O₃.

FIG. 2B is a graph illustrating a relationship between a wavelength and a penetration depth when Ga₂O₃ is irradiated with light.

FIG. 3A is a graph illustrating a relationship between a wavelength and absorptance in GaN.

FIG. 3B is a graph illustrating a relationship between a wavelength and a penetration depth when GaN is irradiated with light.

FIG. 4A is a graph illustrating a relationship between a wavelength and absorptance in SiC.

FIG. 4B is a graph illustrating a relationship between a wavelength and a penetration depth when SiC is irradiated with light.

FIG. 5 is a cross-sectional view schematically illustrating a configuration of one embodiment of an optical heating apparatus.

FIG. 6 is an exemplary spectrum of ultraviolet light emitted from a UV-LED light source.

FIG. 7 is a schematic plan view of the UV-LED light source viewed from the +Z side.

FIG. 8 is a plan view schematically illustrating a configuration of the LED substrate.

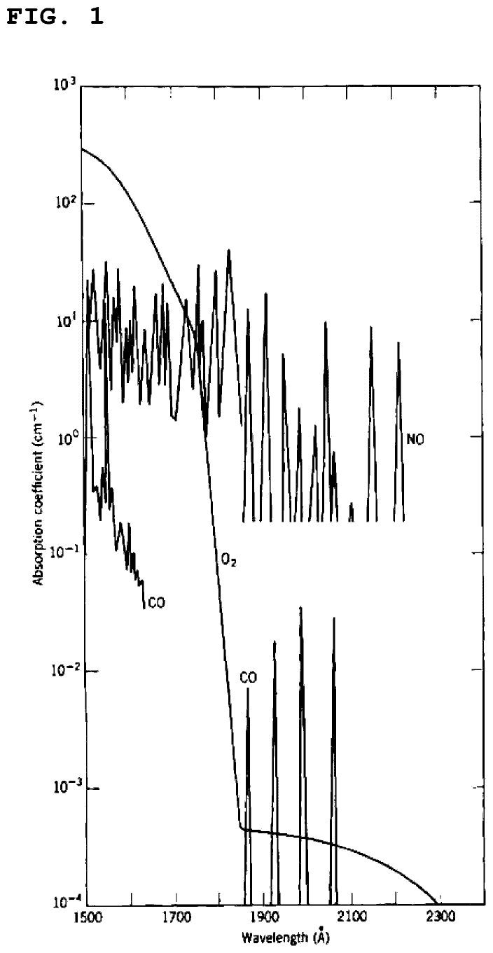

### DETAILED DESCRIPTION OF THE EMBODIMENTS

An optical heating method according to the present invention includes a process (a) in which an object to be treated containing a wide band gap semiconductor is irradiated with ultraviolet light having a peak wavelength in a range of 175 nm to 370 nm emitted from a UV-LED light source and through a window member to heat the object to be treated. Hereinafter, the optical heating method will now be described with reference to the drawings of one embodiment of the optical heating apparatus in which the method is performed.

It is noted that each of the following drawings is merely schematically illustrated. The dimensional ratios and the number of parts on the drawings do not necessarily match the actual dimensional ratios and the actual number of parts.

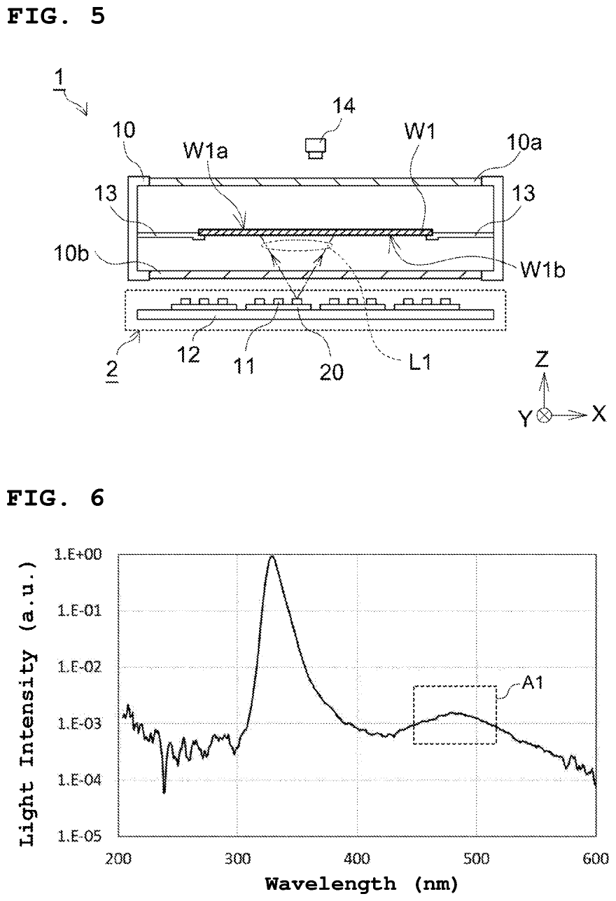

FIG. 5 is a cross-sectional view schematically illustrating a configuration of one embodiment of an optical heating apparatus. The optical heating apparatus 1 shown in FIG. 5 includes a chamber 10 that accommodates an object to be treated W1 containing wide band gap semiconductors, a UV-LED light source 2 and a radiation thermometer 14. The UV-LED light source 2 includes a plurality of LED elements 11 and a support substrate 12 on which the LED elements 11 are mounted. In more detail, the UV-LED light source 2 in this embodiment includes a plurality of LED substrates 20 on each of which a plurality of LED elements 11 is mounted, and these plurality of LED substrates 20 is mounted on the support substrate 12.

In the following explanation, as shown in FIG. 5, the X-Y-Z coordinate system is appropriately used to represent a main surface of the object to be treated W1 as the X-Y plane and a normal direction of the X-Y plane as the Z direction. As shown in FIG. 5, the UV-LED light source 2 and the object to be treated W1 face each other in the Z direction. When described using this notation, FIG. 5 corresponds to a schematic cross-sectional view of the optical heating apparatus 1 when cut in the X-Z plane.

Hereinafter, in the case of expressing the direction with distinguishing a positive direction from a negative direction, a positive or negative sign is assigned such as “+Z direction” or “−Z direction”. In the case of expressing the direction without distinguishing a positive direction from a negative direction, it is simply expressed as “Z direction”.

The UV-LED light source 2 emits ultraviolet light L1 having a peak wavelength in a range of 175 nm to 370 nm. In the present specification, the peak wavelength of the ultraviolet light L1 emitted from the UV-LED light source 2 refers to a wavelength that exhibits the highest light intensity (light output) in the emission spectrum.

FIG. 6 is a spectrum of the ultraviolet light L1 when the UV-LED light source 2 emits the ultraviolet light L1 having a peak wavelength of 325 nm. In FIG. 6, the vertical axis is expressed in logarithmic scale.

The spectrum shown in FIG. 6 indicates that the light intensity in the vicinity of 500 nm, which is a side of a wavelength longer than the peak wavelength, is approximately 0.1% to 0.3% of the light intensity at the peak wavelength (region A1 in FIG. 6). This light is inherent in impurity or defect levels, unavoidably generates when the light source is an LED, and corresponds to the “deep-level emission” described above.

The UV-LED light source 2 provided in the optical heating apparatus 1 has an emission wavelength range that is much shorter than that of the LED lamp provided in the apparatus in the above-mentioned Patent Document 1.

As shown in FIG. 5, chamber 10 is provided with a supporter 13 thereinside. The supporter 13 supports an object to be treated W1 in order to place a main surface W1a and a main surface W1b of the object to be treated W1 on the X-Y plane. In FIG. 5, the main surface W1b of the object to be treated W1 is placed to face the UV-LED light source 2. In other words, the main surface W1a or the main surface W1b is formed with circuit elements, wiring or the like, and the main surface W1b is a surface that is irradiated with the ultraviolet light L1 emitted from the UV-LED light source 2. However, the present invention does not exclude the case that the substrate W1 is a substrate with a bare state having no wiring or the like.

The object to be treated W1 can be supported by the supporter 13 in any manner as long as the main surface W1a thereof is placed on the X-Y plane. For example, the supporter 13 may be provided with a plurality of pin-shaped protrusions, which support the object to be treated W1 at their points thereof.

As shown in FIG. 5, chamber 10 is provided with a first window 10a that faces the main surface W1a of the object to be treated W1 in a state of being supported by supporter 13, and a second window 10b that faces the main surface W1b.

The first window 10a is a window through which the radiation thermometer 14 is used to measure the temperature of the main surface W1a of the object to be treated W1. The radiation thermometer 14 is a thermometer that measures the surface temperature of the object to be measured by receiving light emitted from the object to be measured. In the present embodiment, the radiation thermometer 14 has a sensitivity wavelength range belonging to a predetermined wavelength range of 0.5 μm to 5 μm. Hence, the first window 10a is made of a material that transmits light belonging to the sensitivity wavelength range of the radiation thermometer 14. The first window 10a is, for example, made of typical quartz glass, calcium fluoride, or the like.

The sensitivity wavelength range of the radiation thermometer 14 provided in the optical heating apparatus 1 is on the side of a longer wavelength than the main emission wavelength range of ultraviolet L1 emitted from the UV-LED light source 2. More preferably, the lower limit value of the sensitivity wavelength range of the radiation thermometer 14 is on the side of a longer wavelength than the wavelength at which the deep-level emission contained in the ultraviolet light L1 exhibits the maximum intensity. As mentioned above, the intensity of the deep-level emission is approximately 0.1% to 0.3% of the peak intensity of the ultraviolet light L1; however, the radiation thermometer 14 may falsely measure the temperature of the object to be treated W1 when the deep-level emission has a wavelength that is within the sensitivity wavelength range of the radiation thermometer 14.

In addition, when the peak wavelength of the ultraviolet light L1 emitted from the UV-LED light source 2 becomes shorter, the wavelength at which the deep-level emission exhibits the maximum intensity also shifts toward the side of shorter wavelengths. Hence, in order to minimize the overlap between the wavelength range of the deep-level emission and the sensitivity wavelength range of the radiation thermometer 14 as much as possible, measures that are taken include that the emission wavelength of the UV-LED light source 2 is set to a shorter wavelength or the lower limit of the sensitivity wavelength range of the radiation thermometer 14 is set to a longer wavelength. However, shifting the sensitivity wavelength range of the radiation thermometer 14 to the side of a longer wavelength reduces the ratio detection capability of the detection elements in the radiation thermometer 14, making it difficult to measure temperatures with high accuracy. Hence, the emission wavelength of the UV-LED light source 2 is preferably set to a shorter wavelength in the case of heating the object to be treated W1 while measuring the temperature with high accuracy in the low temperature range.

The second window 10b is used to guide the ultraviolet light L1 emitted from the UV-LED light source 2 onto the main surface W1b of the object to be treated W1. As described above, the ultraviolet light L1 has a peak wavelength in a range of 175 nm to 370 nm. The second window 10b is made of a material having a transmittance of 50% or more to the ultraviolet light L1. As an example, the second window 10b is made of synthetic quartz. In this case, the second window 10b exhibits high transmittance to the ultraviolet light L1 even when the ultraviolet light L1 has a peak wavelength of less than 200 nm. However, the second window 10b may be made of a material suitably selected according to the peak wavelength of the ultraviolet light L1.

FIG. 7 is a schematic plan view of the UV-LED light source 2 viewed from the +Z side. As shown in FIG. 7, the UV-LED light source 2 is configured to arrange a plurality of light source areas 12a on the main surface of the support substrate 12, each light source area 12a including the plurality of LED elements 11. More precisely, the light source area 12a is formed on the LED substrate 20. The plurality of LED substrates 20 is then mounted on the main surface of the support substrate 12.

In the UV-LED light source 2 shown in FIG. 7, the LED substrates 20 constituting the light source areas 12a are arranged in an ordered manner. In the present invention, the arrangement pattern of the LED substrates 20 is not limited; however, the LED substrates 20 are preferably arranged symmetrically each other when viewed in the Z direction. Preferably the LED substrates 20 are typically arranged in a line symmetry, a point symmetry, or a rotational symmetry when viewed in the Z direction. This configuration enables the main surface W1b of the object to be treated W1 to be nearly uniformly irradiated with the ultraviolet light L1.

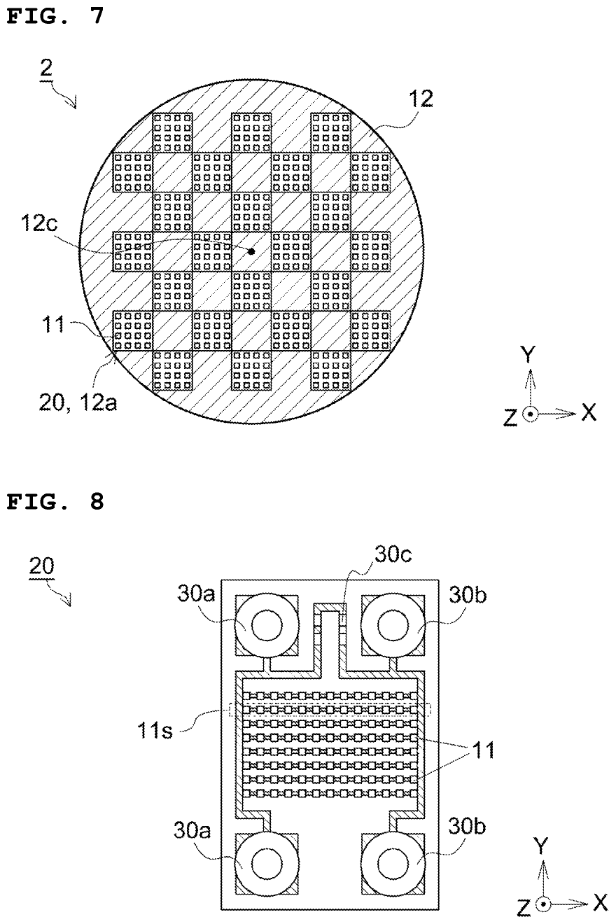

FIG. 8 is a plan view schematically illustrating a configuration of a LED substrate 20. As shown in FIG. 8, the LED substrate 20 includes a plurality of LED elements 11, an anode electrode 30a and a cathode electrode 30b. The plurality of LED elements 11 is electrically connected with the anode electrode 30a and the cathode electrode 30b. In the embodiment shown in FIG. 8, a Zener diode 30c is provided on the LED substrate 20. The Zener diode 30c is connected in parallel with the plurality of LED elements 11 between the anode electrode 30a and the cathode electrode 30b. The Zener diode 30c is disposed to prevent the LED elements 11 from being damaged by static electricity or a surge current.

In the embodiment shown in FIG. 8, the plurality of LED elements 11 mounted on the LED substrate 20 is connected in series-parallel. In other words, a part of the plurality of LED elements 11 is connected in series with each other to constitute an LED element group 11s, and the plurality of LED element groups 11s is connected in parallel with each other.

The plurality of the LED elements 11 is an element that emit the ultraviolet light L1 having a peak wavelength in a range of 175 nm to 370 nm. It is preferable that the peak wavelength of the ultraviolet light L1 emitted from the plurality of LED elements 11 is substantially the same. The term “substantially the same” here is intended to tolerate a wavelength shift caused by the element variations in the manufacturing process. The wavelength shift may be typically tolerated to be within ±5 nm.

As an example, the LED substrate 20 is provided with the LED elements 11 that only emit the ultraviolet light L1 having a peak wavelength of 325 nm thereon. As another example, the LED substrate 20 is provided with the LED elements 11 that only emit the ultraviolet light L1 having a peak wavelength of 260 nm thereon. As yet another example, the LED substrate 20 is provided with the LED elements 11 that only emit the ultraviolet light L1 having a peak wavelength of 310 nm thereon. As yet another example, the LED substrate 20 is provided with the LED elements 11 that only emit the ultraviolet light L1 having a peak wavelength of 365 nm thereon.

According to the optical heating apparatus 1, the ultraviolet light L1 emitted from the UV-LED light source 2, which has a peak wavelength in a range of 175 nm to 370 nm, is absorbed by the object to be treated W1 even if the object to be treated W1 contains a wide band gap semiconductor. Therefore, the optical heating apparatus 1 enables a non-contact heating to the object to be treated W1.

Furthermore, when this light irradiation process is executed, the radiation thermometer 14 is used to receive the light emitted from the object to be treated W1, thus detecting the temperature of the object to be treated W1. As described above, by setting the sensitivity wavelength range of the radiation thermometer 14 to a wavelength longer than the wavelength at which the deep-level emission, which is contained in ultraviolet light L1, exhibits the maximum intensity, the temperature of the object to be treated W1 is prevented from being falsely measured by receiving the light that contains the deep-level emission. In other words, the detection result by the radiation thermometer 14 is used to provide a feedback to the controller (not shown) that controls the light output of the UV-LED light source 2, thus enabling a highly accurate heating of the object to be treated W1 containing the wide band gap semiconductor. It is noted that the main emission wavelength range including the peak wavelength of ultraviolet light L1 is apparently outside the sensitivity wavelength range of the radiation thermometer 14.

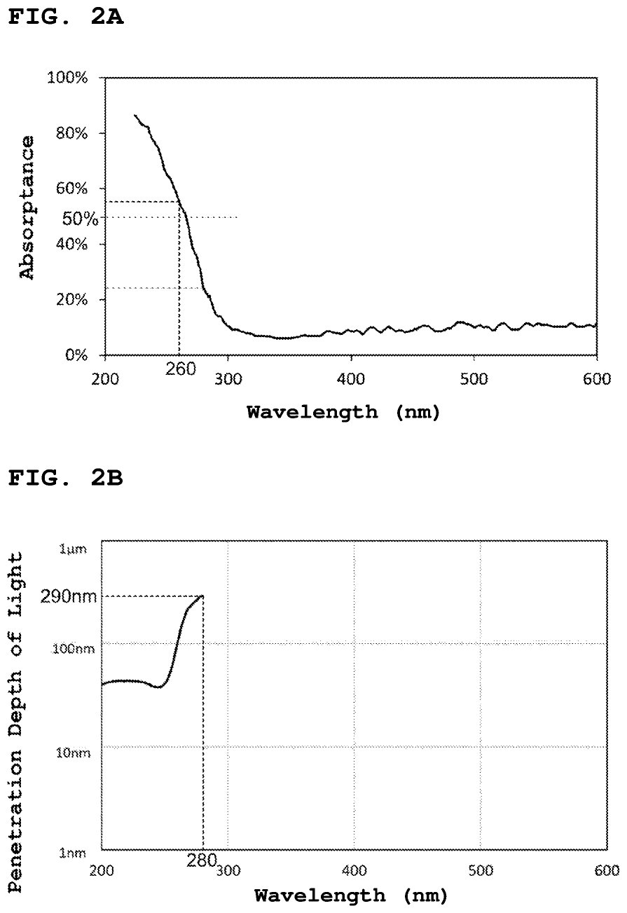

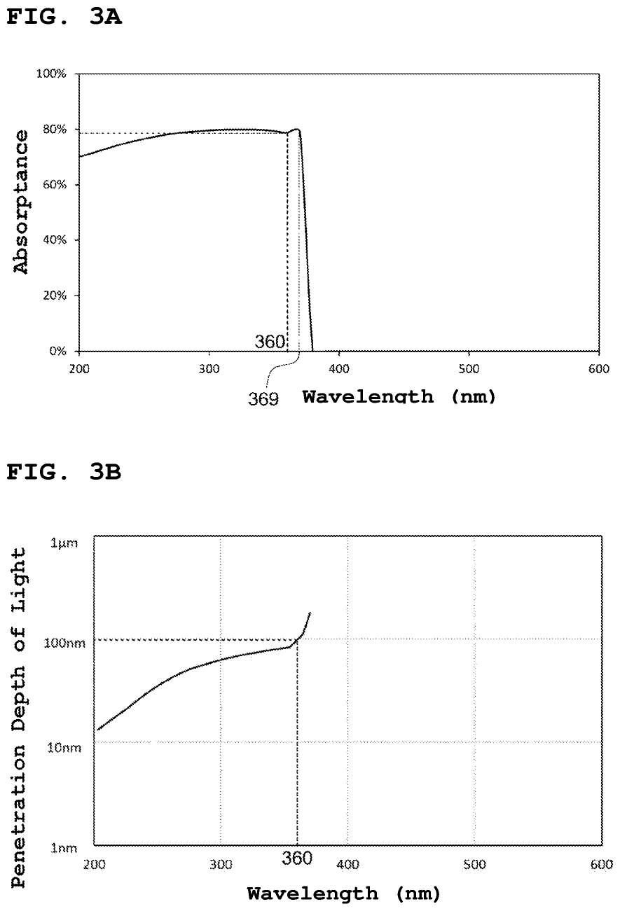

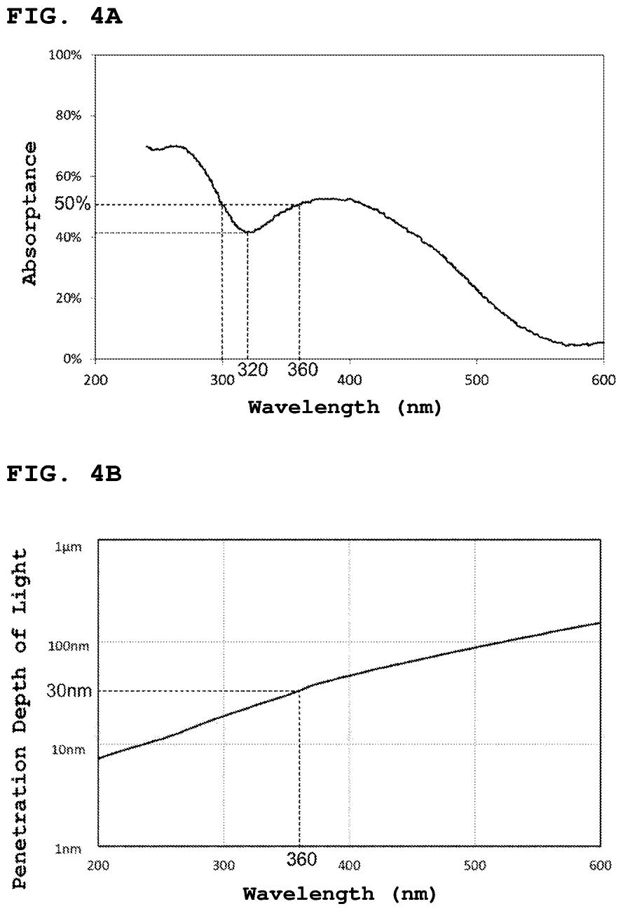

Furthermore, as described above with reference to FIGS. 2B, 3B, and 4C, since the peak wavelength of the ultraviolet light L1 emitted from the UV-LED light source 2 is a short wavelength, the penetration depth of ultraviolet light L1 is confined to the vicinity of the surface. Therefore, heat treatment can be performed on the surface of the object to be treated W1 while suppressing the impact of thermal history and thermal damage to devices that are located in a layer below the surface of the object to be treated W1.

The ultraviolet light L1 preferably has a peak wavelength in a range of 190 nm to 370 nm. This configuration is effective in suppressing the amount of ozone generation, even when the UV-LED light source 2 is placed in the atmosphere.

In contrast, when ultraviolet light L1 has a peak wavelength of less than 190 nm, the UV-LED light source 2 itself may be accommodated in a vacuum or in an enclosed space filled with nitrogen (N₂) gas, and a light extraction window made of the same material as the second window 10b may be provided on a part of the wall of the enclosed space, in order to reduce or suppress the amount of ozone generation.

The peak wavelength of ultraviolet light L1 emitted from the UV-LED light source 2 may be appropriately selected in accordance with the type of wide band gap semiconductor contained in the object to be treated W1. In other words, the type of the UV-LED light source 2 (LED element 11) may be appropriately selected in accordance with the type of wide band gap semiconductor contained in the object to be treated W1, which is to be subject to heat treatment using the optical heating apparatus 1.

Typically, when the wide band gap semiconductor contained in the object to be treated W1 is made of Ga₂O₃, UV-LED light source 2 preferably emits ultraviolet light L1 having a peak wavelength of 300 nm or less. In addition, when the wide band gap semiconductor contained in the object to be treated W1 is made of GaN or SiC, UV-LED light source 2 preferably emits ultraviolet light L1 having a peak wavelength of 360 nm or less.

### Another Embodiment

Hereinafter, another embodiment will be described.

<1> The light source areas 12a illustrated in FIG. 7 each have a square shape; however, this shape is merely an example. Similarly, the LED substrate 20 illustrated in FIG. 8 is a rectangular; however, this shape is also merely an example.

In FIG. 7, a plurality of LED substrates 20 is arranged in a staggered grid on the support substrate 12. However, the plurality of LED substrates 20 may have any arrangement pattern. As another example, the plurality of LED substrates 20 may be arranged in an annular shape around the center 12c of the support substrate 12.

In FIG. 8, each of the plurality of LED element groups 11s mounted on the LED substrate 20 is composed of the LED elements 11 having the same number. However, the number of LED elements 11 constituting each of the plurality of LED element groups 11s may be different from each other in consideration of the difference in a voltage drop that occurs depending on the respective distances from the anode electrode 30a and the cathode electrode 30b.

<2> In the optical heating apparatus 1 shown in FIG. 5, the first window 10a for the temperature measurement with the radiation thermometer 14 is disposed in a side facing the main surface W1a, which is opposite to the main surface W1b that is irradiated with the ultraviolet light L1 with respect to the object to be treated W1. However, in the present invention, the first window 10a may be disposed at any position. For example, the first window 10a may be disposed on the side wall of the chamber 10 or in the side of the main surface W1b.

In the latter case, as described above, the sensitivity wavelength range of the radiation thermometer 14 is adjusted to be considerably outside the main emission wavelength range of the ultraviolet light L1 and also avoid overlapping with the wavelength range in which the deep-level emission exhibits maximum intensity. The configuration reduces a risk of falsely detecting the temperature of the object to be treated W1 even if the ultraviolet light L1 is reflected on the main surface W1b of the object to be treated W1 and the reflected light is received with the radiation thermometer 14 because the wavelength range of the reflected light is outside the sensitivity range of the radiation thermometer 14.

What is claimed is:

1. An optical heating method comprising:
a process (a) in which an object to be treated containing a wide band gap semiconductor is irradiated with ultraviolet light having a peak wavelength in a range of 175 nm to 370 nm emitted from a UV-LED light source through a window member to heat the object to be treated.

2. The optical heating method according to claim 1, further comprising a process (b) in which a radiation thermometer having a sensitivity wavelength range in a predetermined wavelength range of 0.5 μm to 5 μm measures a temperature of the object to be treated by receiving light emitted from the object to be treated during execution of the process (a).

3. The optical heating method according to claim 1, wherein the ultraviolet light has a peak wavelength in a range of 190 nm to 370 nm.

4. The optical heating method according to claim 2, wherein the ultraviolet light has a peak wavelength in a range of 190 nm to 370 nm.

5. The optical heating method according to claim 3, wherein the wide band gap semiconductor is made of Ga₂O₃ and the ultraviolet light has a peak wavelength of 300 nm or less.

6. The optical heating method according to claim 4, wherein the wide band gap semiconductor is made of Ga₂O₃ and the ultraviolet light has a peak wavelength of 300 nm or less.

7. The optical heating method according to claim 3, wherein the wide band gap semiconductor is made of GaN or SiC and the ultraviolet light has a peak wavelength of 360 nm or less.

8. The optical heating method according to claim 4, wherein the wide band gap semiconductor is made of GaN or SiC and the ultraviolet light has a peak wavelength of 360 nm or less.

9. An optical heating apparatus for heating a wide band gap semiconductor comprising:
a chamber that accommodates an object to be treated containing a wide band gap semiconductor;
a supporter that supports the object to be treated in the chamber;
a UV-LED light source that emits ultraviolet light having a peak wavelength in a range of 175 nm to 370 nm; and
a window member that allows the ultraviolet light emitted from the UV-LED light source to pass through and guide the ultraviolet light onto the object to be treated.

10. The optical heating apparatus for heating a wide band gap semiconductor according to claim 9, wherein the UV-LED light source includes a plurality of LED substrates on which a plurality of LED elements is mounted, and the plurality of LED substrates is arranged in a line symmetry, a point symmetry, or a rotational symmetry when viewed in a normal direction of a face of the LED substrates.
